(19) United States
(12) Patent Application Publication
(10) Pub. No.: US 2025/0283927 A1
(43) Pub. Date: Sep. 11, 2025

(54) SILICON STRUCTURES TO MONITOR DEVICE CAPACITANCES

(71) Applicant: NVIDIA Corp., Santa Clara, CA (US)

(72) Inventors: Manish Umedlal Patel, Bangalore (IN); Kinshuk Srivastava, Bangalore (IN); Tezaswi Raja, San Jose, CA (US)

(73) Assignee: NVIDIA Corp., Santa Clara, CA (US)

(21) Appl. No.: 18/601,230

(22) Filed: Mar. 11, 2024

(51) Int. Cl. G01R 27/26; H01L 27/092

(52) U.S. Cl. CPC G01R 27/2605; H10D 84/856

(57) ABSTRACT

A capacitive monitoring structure includes a ring oscillator and dynamically configurable capacitive load circuits coupled between stages of the ring oscillator. The oscillation frequency of the ring oscillator changes in response to settings applied to the capacitive load circuits to change a capacitance applied to the ring oscillator by the capacitive load circuits, where the capacitance may be one of a transistor drain capacitance, a transistor gate capacitance, and a Miller capacitance.

### BACKGROUND

Monitoring device capacitance in advanced process nodes is a challenging problem. Mismatching between transistor components due to capacitive effects (drain capacitance, gate capacitance, and Miller Capacitance, for example) may lead to poor or undesirable performance characteristics. It is therefore desirable to enable precision monitoring and measurement of device capacitive effects.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts a capacitance monitoring circuit in one embodiment.

FIG. 2 depicts an example distribution of capacitance monitoring circuits on an integrated circuit.

FIG. 3A depicts an embodiment of a structure to monitor PFET/PMOS transistor drain capacitance.

FIG. 3B depicts an embodiment of a structure to monitor NFET/NMOS transistor drain capacitance.

FIG. 3C depicts the structure of FIG. 3B coupled as a load to the ring oscillator.

FIG. 4A and FIG. 4B depicts exemplary structures to monitor PFET/PMOS and NFET/NMOS transistor gate capacitance, respectively.

FIG. 5 depicts an exemplary structure to monitor the transistor drain capacitance of a PFET/PMOS and NFET/NMOS stack in a single device under test structure.

FIG. 6 depicts an exemplary structure to monitor Miller capacitance as the effective capacitance between gate-drain and gate-source.

FIG. 7 depicts exemplary scenarios for use of a capacitance monitoring circuit 702.

### DETAILED DESCRIPTION

Embodiments of in-silicon monitor structures are disclosed that enable measurement of transistor device capacitances under varying voltage biasing conditions. Precise monitoring of these capacitances enables improvements in device parameter correlation, silicon debug, and device performance.

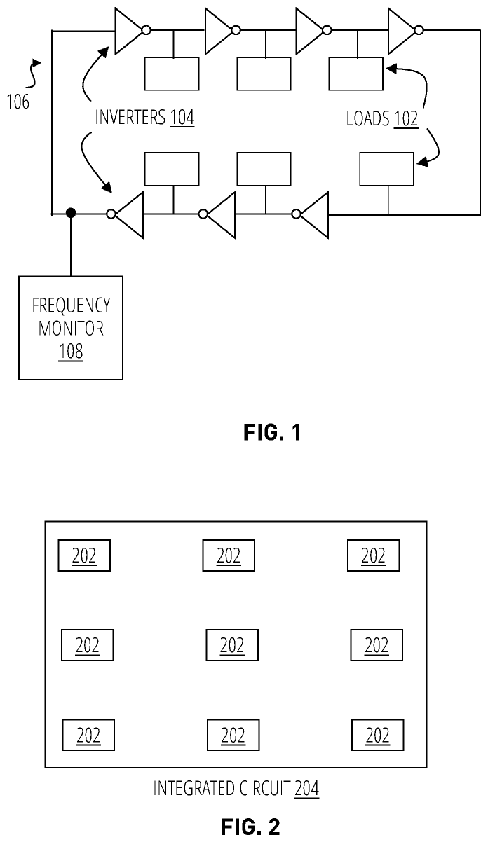

Capacitance monitoring structures such as depicted in FIG. 1 may comprise a ring oscillator to monitor device capacitances across varying transistor bias and threshold voltages. Loads 102 comprising the characteristics of the devices to monitor are configured on inverters 104 of the ring oscillator 106 and the capacitance of these loads 102 influences the frequency of the ring oscillator 106, which is detected by the frequency monitor 108. In general the ring oscillator may comprise any odd number of stages, in some cases preferably a prime number of stages.

The load types may be selected to model various device capacitance possibilities across different device and voltage characteristics.

The use of inverter chains to implement ring oscillators is common, but other mechanisms known in the art to implement ring oscillators may also be utilized, with the capacitive loading elements coupled between the ring oscillator stages.

FIG. 2 depicts an example distribution of capacitive monitoring circuits 202 on an integrated circuit 204. The capacitive monitoring circuits 202 are disposed at different locations of the integrated circuit 204 where different process-voltage-temperature (PVT) conditions may occur, to model and monitor capacitive characteristics of transistors in each of those areas. Each area of the integrated circuit 204 may have a mixture of different capacitive monitoring circuit structures disposed therein, to monitor different types of device capacitances for both NMOS and PMOS (or NFET and PFET) device types. To improve the sensitivity of the capacitive monitoring circuit 202, the size of the NMOS and PMOS devices used to generate the capacitances in the capacitive monitoring circuit 202 may in some embodiments be larger than the size of the NMOS and PMOS devices they model in the integrated circuit 204. In this description and in the Claims, it should be understood that NFET can be substituted for NMOS without loss of accuracy, and vice versa, and likewise PFET can be substituted for PMOS without loss of accuracy, and vice versa.

The capacitive monitoring circuits 202 may be formed on a silicon wafer or other substrate as wafer acceptance testing (WAT) structures, also known as process control monitoring (PCM) circuits. The capacitive monitoring circuits 202 may be operated to generate test results at the fabrication facility of the integrated circuit 204 for every wafer. Test results may be generated for each site (or “drop-in”) on the wafer where a capacitive monitoring circuit 202 is formed.

Transistor drain capacitance refers to the capacitance that exists between the drain terminal and other terminals of a transistor, such as the substrate/bulk, source, and gate. It is an inherent capacitance that occurs in both bipolar junction transistors (BJTs) and metal-oxide-semiconductor field-effect transistors (MOSFETs). In MOSFETs, the capacitance between the drain and other terminals is primarily due to a) the overlap between the drain region and the gate oxide, and b) reverse bias junction capacitance with the bulk. This capacitance may be referred to as the “drain or source junction capacitance” in MOSFET models. Transistor drain capacitance plays a significant role in determining the behavior of the transistor in various circuit applications. It affects important performance parameters such as the gain, frequency response, switching speed, and power consumption of the device.

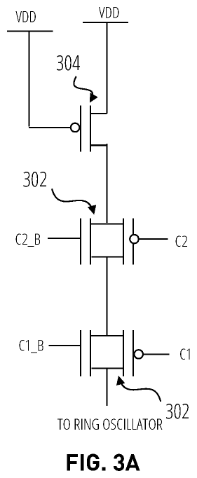

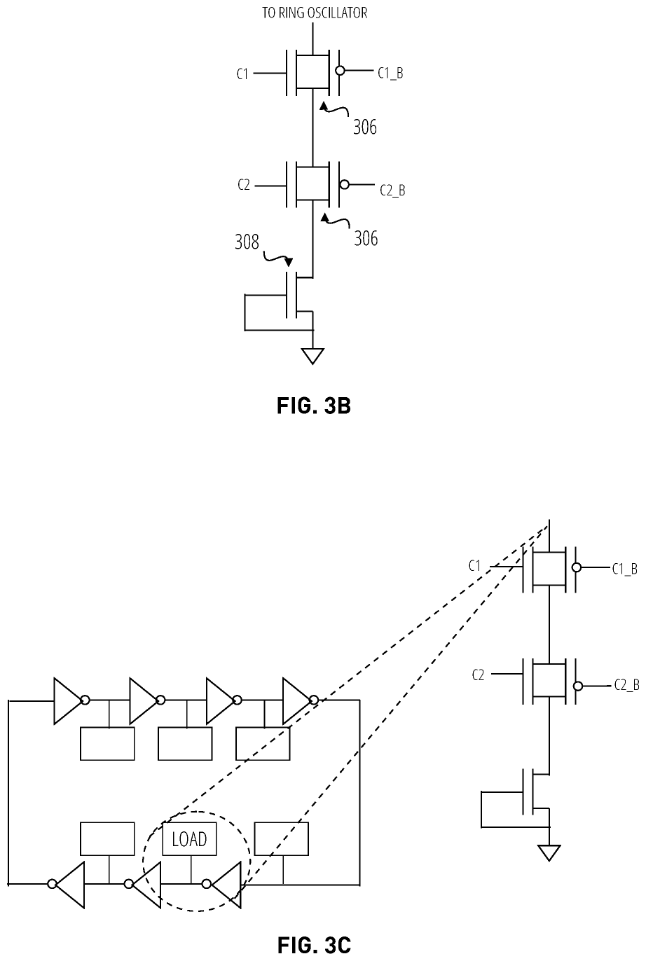

FIG. 3A depicts an embodiment of a structure to monitor PMOS transistor drain capacitance. FIG. 3B depicts an embodiment of a structure to monitor NMOS transistor drain capacitance. Each structure includes a pair of transmission gates controlled by signals C1 and C2. Other numbers of transmission gates may also be utilized to generate additional capacitive loads.

The transmission gates 302 of the structure in FIG. 3A may be configured asymmetrically, such that the PMOS transistors are substantially larger (greater fabrication area) than the NMOS transistors therein. For example, the PMOS devices may be an order of magnitude larger than the NMOS devices. The header PMOS transistor 304 in the structure of FIG. 3A is configured to be permanently OFF (non-conducting) when power is applied.

The transmission gates 306 of the structure in FIG. 3B may be configured asymmetrically, such that the NMOS transistors are substantially larger than the PMOS transistors therein. The footer NMOS transistor 308 in the structure of FIG. 3B is configured to be permanently OFF.

Depending upon the settings for these control signals, the load capacitance of these structures will vary, which will in turn affect the ring oscillator frequency (C1_B and C2_B represent the complement values of C1 and C2, respectively). In the structures depicted in FIG. 3A and FIG. 3B, the internal nodes charge and discharge to VDD (upper supply voltage level) and GND (e.g., VSS or lower supply voltage level). FIG. 3C depicts the structure of FIG. 3B coupled as a load to the ring oscillator.

Depending upon the settings for control signals C1 and C2, the capacitances of the devices under test (PMOS transistors in FIG. 3A, and NMOS transistors in FIG. 3B) will vary, which will in turn affect the ring oscillator frequency. The internal nodes of the load structures charge and discharge, respectively, to VDD and GND levels. Across PVT corners, a significant ring oscillator frequency difference (˜50%) may be detected between consecutive operating modes. Table 1 depicts operating modes for the load structure depicted in FIG. 3A.

TABLE 1

| | | Ring | |
|---|---|---|---|
| C1 | C2 | oscillator | Comment |
| 0 | 0 | Active | PFET drain capacitance test structure. Highest PFET drain |
| | | | capacitance exhibited at ring oscillator. |
| 0 | 1 | Active | PFET drain capacitance test structure. Second highest PFET |
| | | | drain capacitance exhibited at ring oscillator. |
| 1 | * | Active | PFET drain capacitance test structure. Lowest PFET drain |
| | | | capacitance exhibited at ring oscillator (baseline). |

Table 2 depicts operating modes for the load structure depicted in FIG. 3B.

TABLE 2

| | | Ring | |
|---|---|---|---|
| C1 | C2 | oscillator | Comment |
| 1 | 1 | Active | NFET drain capacitance test structure. Highest NFET drain |
| | | | capacitance exhibited at ring oscillator. |
| 1 | 0 | Active | NFET drain capacitance test structure. Second highest NFET |
| | | | drain capacitance exhibited at ring oscillator. |
| 0 | * | Active | NFET drain capacitance test structure. Lowest NFET drain |
| | | | capacitance exhibited at ring oscillator (baseline). |

Transistor gate capacitance refers to the capacitance that exists between the gate terminal and other terminals of a transistor, such as the source, bulk, and drain. It is an important parameter in both bipolar junction transistors (BJTs) and metal-oxide-semiconductor field-effect transistors (MOSFETs). In MOSFETs, the gate capacitance is predominantly a result of the overlap between the gate electrode and the underlying oxide layer, known as the gate oxide capacitance. This capacitance is often divided into components: the capacitance between the gate and the source (“gate-source capacitance” or “Cgs”), the capacitance between the gate and the bulk, and the capacitance between the gate and the drain (“gate-drain capacitance” or “Cgd”). Transistor gate capacitance directly affects the performance of the transistor in various circuit applications. It determines the input impedance, gain, bandwidth, and switching speed of the device. Therefore, accurate modeling and characterization of gate capacitance are crucial for designing and optimizing transistor circuits.

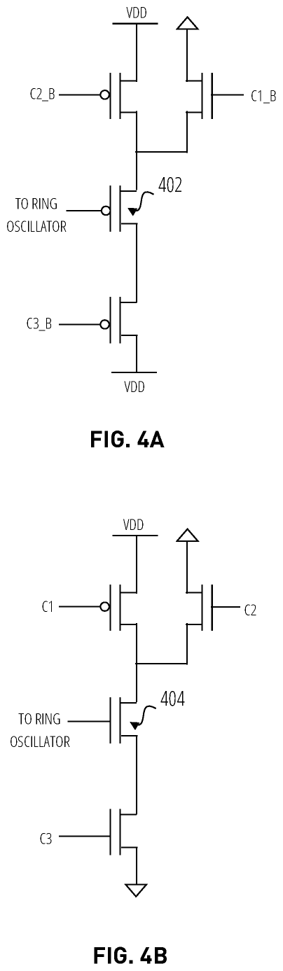

FIG. 4A and FIG. 4B depicts exemplary structures to monitor PFET and NFET transistor gate capacitance, respectively. Depending upon the control signal settings (see Table 2), a different amount of gate capacitance will exhibit at the load node on the ring oscillator.

In the structure of FIG. 4A, the control signals determine whether the drain and/or source terminals of the PMOS transistor 402 are set to VDD or ground/VSS potential. In the structure of FIG. 4B, the control signals determine whether the drain and/or source terminals of the NMOS transistor 404 are set to VDD or ground/VSS potential.

Modes that result in a short circuit path between VDD and GND are not used. The ring oscillator frequency varies with changes in the gate capacitance arising from different combinations of the control signal settings. Table 3 below depicts operating modes for the load structure in FIG. 4A.

TABLE 3

| | | | Ring | |
|---|---|---|---|---|
| C1 | C2 | C3 | oscillator | Comment |
| 0 | 0 | 0 | Active | PFET gate capacitance test structure. Particular gate |
| | | | | capacitance exhibited at ring oscillator. |
| 0 | * | 1 | illegal | X |
| | | | mode | |
| 0 | 1 | * | illegal | X |
| | | | mode | |
| 1 | 0 | 0 | Active | PFET gate capacitance test structure. Lowest PFET gate |
| | | | | capacitance exhibited at ring oscillator (baseline). |
| 1 | 0 | 1 | Active | PFET gate capacitance test structure. Particular PFET |
| | | | | gate capacitance exhibited at ring oscillator. |
| 1 | 1 | 0 | Active | PFET gate capacitance test structure. Particular PFET |
| | | | | gate capacitance exhibited at ring oscillator. |
| 1 | 1 | 1 | Active | PFET gate capacitance test structure. Highest PFET gate |
| | | | | capacitance exhibited at ring oscillator. |

Table 4 below depicts operating modes for the load structure in FIG. 4B.

TABLE 4

| | | | Ring | |
|---|---|---|---|---|
| C1 | C2 | C3 | oscillator | Comment |
| 0 | 0 | 0 | Active | NFET gate capacitance test structure. Particular NFET |
| | | | | gate capacitance exhibited at ring oscillator. |
| 0 | * | 1 | illegal | X |
| | | | mode | |
| 0 | 1 | * | illegal | X |
| | | | mode | |
| 1 | 0 | 0 | Active | NFET gate capacitance test structure. Lowest NFET gate |
| | | | | capacitance exhibited at ring oscillator (baseline). |
| 1 | 0 | 1 | Active | NFET gate capacitance test structure. Particular NFET |
| | | | | gate capacitance exhibited at ring oscillator. |
| 1 | 1 | 0 | Active | NFET gate capacitance test structure. Particular NFET |
| | | | | gate capacitance exhibited at ring oscillator. |
| 1 | 1 | 1 | Active | NFET gate capacitance test structure. Highest NFET gate |
| | | | | capacitance exhibited at ring oscillator. |

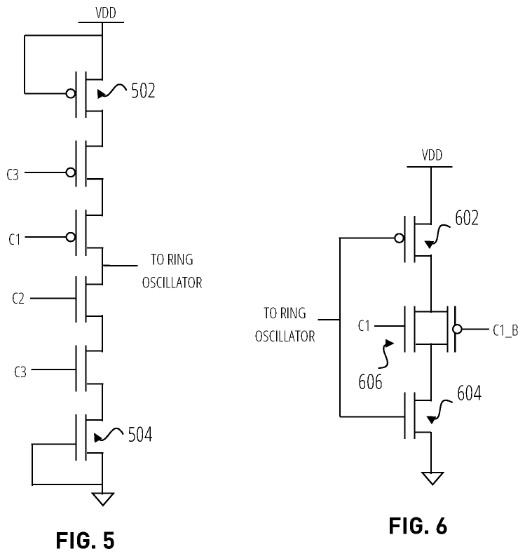

FIG. 5 depicts an exemplary structure to monitor transistor drain capacitance for a (potentially mixed) stack of FET devices. Different load capacitances may be generated via different combinations of control signals as per Table 5.

TABLE 5

| | | | Ring | |
|---|---|---|---|---|
| C1 | C2 | C3 | oscillator | Comment |
| 0 | 0 | 0 | Active | Mixed device type drain capacitance test structure. |
| | | | | Highest PFET drain capacitance/lowest NFET drain |
| | | | | capacitance exhibited at ring oscillator. |
| 0 | 0 | 1 | Active | Mixed device type drain capacitance test structure. |
| | | | | Lowest NFET drain capacitance exhibited at ring |
| | | | | oscillator; PFET drain capacitance contribution at ring |
| | | | | oscillator greater than NFET drain capacitance |
| | | | | contribution. |
| 0 | 1 | 0 | Active | Mixed-device-type drain capacitance test structure. PFET |
| | | | | drain capacitance contribution greater than NFET drain |
| | | | | capacitance contribution. Mixed-device-type drain |
| | | | | capacitance exhibited at ring oscillator. |
| 0 | 1 | 1 | Active | Mixed-device-type drain capacitance test structure. NFET |
| | | | | drain capacitance contribution greater than PFET drain |
| | | | | capacitance contribution. Mixed-device-type drain |
| | | | | capacitance exhibited at ring oscillator. |
| 1 | 0 | * | Active | Mixed device type drain capacitance test structure. |
| | | | | Lowest overall drain capacitance exhibited at ring |
| | | | | oscillator (baseline). |
| 1 | 1 | 0 | Active | Mixed device type drain capacitance test structure. |
| | | | | Lowest PFET drain capacitance exhibited at ring |
| | | | | oscillator; NFET drain capacitance contribution at ring |
| | | | | oscillator greater than PFET drain capacitance |
| | | | | contribution. |
| 1 | 1 | 1 | Active | Mixed device type drain capacitance test structure. |
| | | | | Highest NFET drain capacitance exhibited at ring |
| | | | | oscillator; lowest PFET drain capacitance exhibited at |
| | | | | ring oscillator. |

The structure in FIG. 5 does not include a transmission gate, and the internal nodes charge and discharge to VDD-Vt and Vt, respectively. The header PMOS transistor 502 and the footer NMOS transistor 504 are configured to both be permanently turned OFF. By selective application of the control signals C1-C3, this structure has general utility for monitoring capacitive effects in mixed NFET/PFET stacks.

Miller capacitance, also known as Miller's capacitance or Miller effect, is a phenomenon that occurs in some MOSFET configurations. When a transistor is used in such configurations a change in voltage at one node is amplified and coupled to another node through capacitive coupling, increasing the effective capacitance between the nodes. The Miller capacitive coupling is typically between an input to the transistor (e.g., a gate) and an amplifying output of the transistor, e.g., the drain. The Miller capacitance effect can have detrimental consequences in circuit performance, including reduced bandwidth, phase distortion, and decreased stability.

FIG. 6 depicts an exemplary structure to monitor Miller capacitance as the effective capacitance between gate-drain and gate-source. Table 6 depicts control settings for this load structure.

TABLE 6

| | Ring | |
|---|---|---|
| C1 | oscillator | Comment |
| 1 | Active | Miller capacitance exhibited at ring oscillator |
| 0 | Active | No Miller capacitance exhibited at ring oscillator |

When C1=0, the Miller capacitance between the PMOS transistor 602 and NMOS transistor 604 is effectively zero. When C1=1, the transmission gate 606 is activated, there is an opposite transition between the gates and drains of the PMOS transistor 602 and the NMOS transistor 604, which generates the Miller capacitance.

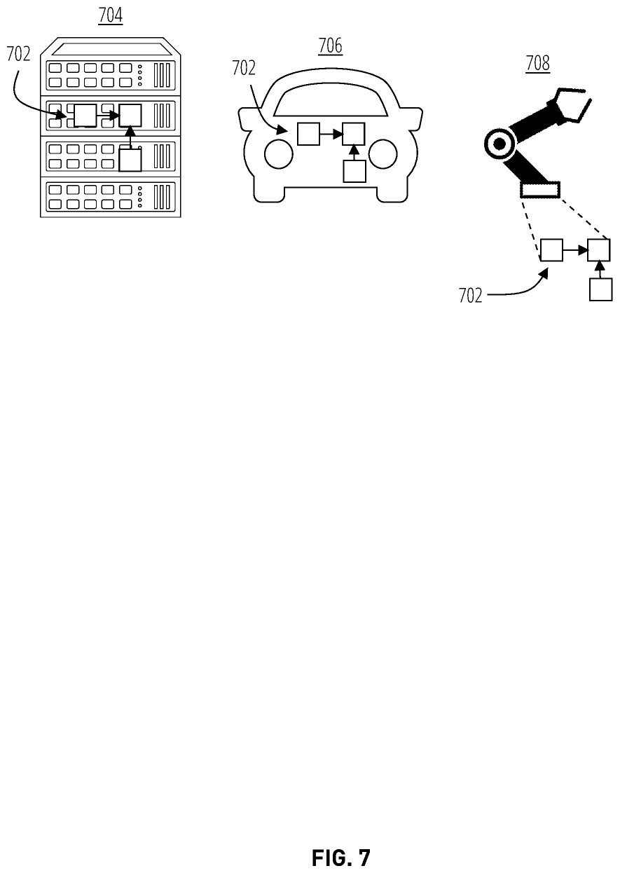

FIG. 7 depicts exemplary scenarios for use of a capacitance monitoring circuit 702. A capacitance monitoring circuit 702 may be utilized in a computing system 704, a vehicle 706, and a robot 708, to name just a few examples. The capacitance monitoring circuit 702 may comprise loaded ring oscillator circuit(s) in accordance with the mechanisms described herein.

### LISTING OF DRAWING ELEMENTS

102 loads
104 inverters
106 ring oscillator
108 frequency monitor
202 capacitive monitoring circuit
204 integrated circuit
302 transmission gate
304 PMOS transistor
306 transmission gate
308 NMOS transistor
402 PMOS transistor
404 NMOS transistor
502 PMOS transistor
504 NMOS transistor
602 PMOS transistor
604 NMOS transistor
606 transmission gate
702 capacitance monitoring circuit
704 computing system
706 vehicle
708 robot

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112 (f) for that claim element. Accordingly, claims in this application that do not otherwise include the “means for” [performing a function] construct should not be interpreted under 35 U.S.C § 112 (f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the intended invention as claimed. The scope of inventive subject matter is not limited to the depicted embodiments but is rather set forth in the following Claims.

What is claimed is:

1. A circuit comprising:
a ring oscillator; and
a plurality of dynamically configurable capacitive load circuits coupled between stages of the ring oscillator.

2. The circuit of claim 1, wherein one of the capacitive load circuits is coupled between each pair of stages of the ring oscillator.

3. The circuit of claim 1, wherein the capacitive load circuits are identical circuits.

4. The circuit of claim 3, wherein each of the capacitive load circuits comprises an always-OFF PFET or PMOS.

5. The circuit of claim 3, wherein each of the capacitive load circuits comprises an always-OFF NFET or NMOS.

6. The circuit of claim 3, wherein each of the capacitive load circuits is dynamically configurable to apply one of a plurality of PFET or PMOS drain capacitances on the ring oscillator.

7. The circuit of claim 6, wherein each of the capacitive load circuits comprises at least one transmission gate.

8. The circuit of claim 7, wherein each transmission gate comprises a PFET or PMOS and an NFET or NMOS that is smaller than the PFET or PMOS.

9. The circuit of claim 3, wherein each of the capacitive load circuits is dynamically configurable to apply one of a plurality of NFET or NMOS drain capacitances on the ring oscillator.

10. The circuit of claim 9, wherein each of the capacitive load circuits comprises at least one transmission gate.

11. The circuit of claim 10, wherein each transmission gate comprises an NFET or NMOS and a PFET or PMOS that is smaller than the NFET or NMOS.

12. The circuit of claim 3, wherein each of the capacitive load circuits is dynamically configurable to apply one of a plurality of PFET or PMOS gate capacitances on the ring oscillator.

13. The circuit of claim 3, wherein each of the capacitive load circuits is dynamically configurable to apply one of a plurality of NFET or NMOS drain capacitances on the ring oscillator.

14. The circuit of claim 3, wherein each of the capacitive load circuits is dynamically configurable to present a Miller capacitance on the ring oscillator.

15. A silicon wafer comprising:
a plurality of capacitive monitoring structures, each comprising:
a ring oscillator; and
a plurality of capacitive load circuits coupled to the ring oscillator, the capacitive load circuits dynamically configurable to apply to the ring oscillator one of (a) a plurality of transistor drain capacitances, (b) a plurality of transistor gate capacitances, and (c) a Miller capacitance.

16. The silicon wafer of claim 15, the capacitive monitoring structures distributed throughout the silicon wafer.

17. The silicon wafer of claim 15, wherein the capacitive load circuits of any particular one of the capacitive monitoring structures comprise an identical structure.

18. The silicon wafer of claim 15, the capacitive load circuits of at least some of the capacitive monitoring structures comprising one or both of an always-OFF PFET or PMOS and an always-OFF NFET or NMOS.

19. The silicon wafer of claim 15, the capacitive load circuits of at least some of the capacitive monitoring structures comprising at least one transmission gate.

20. A silicon wafer test process comprising:
activating a ring oscillator;
dynamically reconfiguring capacitive load circuits coupled between stages of the ring oscillator; and
measuring changes in a frequency of the ring oscillator in response to the dynamically reconfiguring of the capacitive load circuits.
